(19) United States
(12) Patent Application Publication
(10) Pub. No.: US 2025/0219352 A1
(43) Pub. Date: Jul. 3, 2025

(54) SEMICONDUCTOR DEVICE

(71) Applicant: Nippon Telegraph and Telephone Corporation, Tokyo (JP)

(72) Inventors: Wataru Kobayashi, Tokyo (JP); Manabu Mitsuhara, Tokyo (JP); Shigeru Kanazawa, Tokyo (JP)

(21) Appl. No.: 18/851,584

(22) PCT Filed: Apr. 1, 2022
(86) PCT No.: PCT/JP2022/016990

§ 371 Date: Sep. 26, 2024

(51) Int. Cl. H01S 5/026

(52) U.S. Cl. CPC H01S 5/0265

(57) ABSTRACT

The semiconductor device includes a substrate made of a semi-insulating compound semiconductor, a first optical active element formed on the substrate, a second optical active element formed on the substrate, and an optical waveguide that optically connects the first optical active element and the second optical active element. The semiconductor device further includes an etching stop layer formed over the entire region on the substrate. The first optical active element, the optical waveguide, and the second optical active element are formed on the etching stop layer.

### CROSS-REFERENCE TO RELATED APPLICATIONS

This application is a national phase entry of PCT Application No. PCT/JP2022/016990, filed on Apr. 1, 2022, which application is hereby incorporated herein by reference.

### TECHNICAL FIELD

The present invention relates to a semiconductor device in which a plurality of optical active elements are integrated.

### BACKGROUND

In optical communication, a light source having a modulation function is used. For example, in optical communication of a relatively short distance with a transmission distance of 100 km or less, an electroabsorption-modulater intergrated distributed feedback laser (EML) in which an electro-absorption type optical modulator and a DFB laser are integrated is used.

In the EML of the related art, a DFB laser for generating light as a carrier wave and an EA modulator for modulating the carrier wave are monolithically integrated on a single semiconductor substrate. In this configuration, a conductive polarity (mainly, an n-polarity InP substrate) is used for the semiconductor substrate. Therefore, the electrical polarity of the substrate in the portion of each integrated element is inevitably short-circuited in terms of structure. Therefore, when the DFB laser and the EA modulator are operated, the substrate is set to GND, a positive polarity voltage is applied to the DFB laser part, and a negative polarity voltage is applied to the EA modulator. In this configuration, the EA modulator is driven by applying a single-phase modulation signal. For example, one of electrodes of the EA modulator is connected to GND to perform single-phase driving.

### CITATION LIST

### Non Patent Literature

NPL 1 W. Kobayashi et al., “Design and Fabrication of Wide Wavelength Range 25.8-Gb/S, 1.3-μM, Push-Pull-Driven DMLs”, Journal of Lightwave Technology, vol. 32, No. 1, pp. 3-9, 2014.

### SUMMARY

### Technical Problem

In order to maximize the characteristics of the EA modulator, it is desirable to perform differential driving. This is because the differential driving has the effect of improving the S/N ratio of the optical waveform by suppressing the common mode noise, and halving of the modulation amplitude voltage applied to each signal line (NPL 1). However, in the structure of the related art, since the substrate side is short-circuited, the DFB laser is single-phase driven, and the EA modulator cannot be differentially driven. In this way, the conventional technique has a problem that two optical active elements to be monolithically integrated cannot be driven by different methods.

Embodiments of the present invention have been made to solve the above-described problems, and an object thereof is to drive two monolithically integrated optical active elements by different methods.

### Solution to Problem

A semiconductor device according to embodiments of the present invention includes a substrate made of a semi-insulating compound semiconductor; a first optical active element which includes a first lower semiconductor layer of a first conductivity type, a first active layer formed on the first lower semiconductor layer, and an upper semiconductor layer of a second conductivity type formed on the first active layer, and is formed on the substrate; a second optical active element which includes a second lower semiconductor layer of a first conductivity type, a second active layer formed on the second lower semiconductor layer, and an upper semiconductor layer formed on the second active layer, and is formed on the substrate; and an optical waveguide which includes a semi-insulating or undoped third lower semiconductor layer, a third active layer formed on the third lower semiconductor layer, and an upper semiconductor layer formed on the third active layer, is formed on the substrate, is disposed between the first optical active element and the second optical active element, functions as an electric separation part between the first optical active element and the second optical active element, and optically connects the first optical active element and the second optical active element.

### Advantageous Effects

As described above, according to embodiments of the present invention, since the first optical active element and the second optical active element are formed on the substrate made of a semi-insulating compound semiconductor, and the optical waveguide functioning as the electric separation part is provided between them, two monolithically integrated optical active elements can be driven by different methods.

### BRIEF DESCRIPTION OF THE DRAWINGS

FIG. 1 is a cross-sectional view showing a configuration of a semiconductor device according to an embodiment of the present invention.

FIG. 2A is a distribution diagram showing calculation results of an electric field intensity distribution in a cross section perpendicular to a waveguide direction in a first optical active element 102.

FIG. 2B is a distribution diagram showing calculation results of the electric field intensity distribution in a cross section perpendicular to the waveguide direction in the first optical active element 102.

FIG. 2C is a distribution diagram showing calculation results of the electric field intensity distribution in a cross section perpendicular to the waveguide direction in the first optical active element 102.

FIG. 3 is a configuration diagram showing a configuration of a model used in the simulation performed regarding optical coupling between the first optical active element 102 and an optical waveguide 104.

FIG. 4 is a characteristics diagram showing calculation results of an optical coupling coefficient with respect to a variation Δz of a thickness z of a third lower semiconductor layer 141 of the optical waveguide 104.

FIG. 5 is a characteristic diagram showing calculation results of the optical coupling efficiency with respect to a difference AW of the waveguide width.

FIG. 6A is a cross-sectional view of a plane parallel to the waveguide direction showing a state of a semiconductor device in an intermediate process for explaining a method for manufacturing a semiconductor device according to an embodiment of the present invention.

FIG. 6B a cross-sectional view of a plane parallel to the waveguide direction showing the state of the semiconductor device in the intermediate process for explaining the method for manufacturing a semiconductor device according to an embodiment of the present invention.

FIG. 6C a cross-sectional view of a plane parallel to the waveguide direction showing the state of the semiconductor device in the intermediate process for explaining the method for manufacturing a semiconductor device according to an embodiment of the present invention.

FIG. 6D is a cross-sectional view of a plane parallel to the waveguide direction showing the state of the semiconductor device in the intermediate process for explaining the method for manufacturing a semiconductor device according to an embodiment of the present invention.

FIG. 6E is a cross-sectional view of a plane parallel to the waveguide direction showing the state of the semiconductor device in the intermediate process for explaining the method for manufacturing a semiconductor device according to an embodiment of the present invention.

FIG. 6F is a cross-sectional view of a plane parallel to the waveguide direction showing the state of the semiconductor device in the intermediate process for explaining the method for manufacturing a semiconductor device according to an embodiment of the present invention.

FIG. 6G is a cross-sectional view of a plane perpendicular to the waveguide direction showing the state of the semiconductor device in the intermediate process for explaining the method for manufacturing a semiconductor device according to an embodiment of the present invention.

FIG. 6H is a cross-sectional view of a plane perpendicular to the waveguide direction showing the state of the semiconductor device in the intermediate process for explaining the method for manufacturing a semiconductor device according to an embodiment of the present invention.

FIG. 6I is a cross-sectional view of a plane perpendicular to the waveguide direction showing the state of the semiconductor device in the intermediate process for explaining the method for manufacturing a semiconductor device according to an embodiment of the present invention.

FIG. 7A is a cross-sectional view of a plane perpendicular to the waveguide direction showing a state of a semiconductor device in an intermediate process for explaining another method for manufacturing a semiconductor device according to an embodiment of the present invention.

FIG. 7B is a cross-sectional view of a plane perpendicular to the waveguide direction showing the state of the semiconductor device in the intermediate process for explaining another method for manufacturing a semiconductor device according to an embodiment of the present invention.

FIG. 7C is a cross-sectional view of a plane perpendicular to the waveguide direction showing the state of the semiconductor device in the intermediate process for explaining another method for manufacturing a semiconductor device according to an embodiment of the present invention.

FIG. 7D is a cross-sectional view of a plane perpendicular to the waveguide direction showing the state of the semiconductor device in the intermediate process for explaining another method for manufacturing a semiconductor device according to an embodiment of the present invention.

### DETAILED DESCRIPTION OF ILLUSTRATIVE EMBODIMENTS

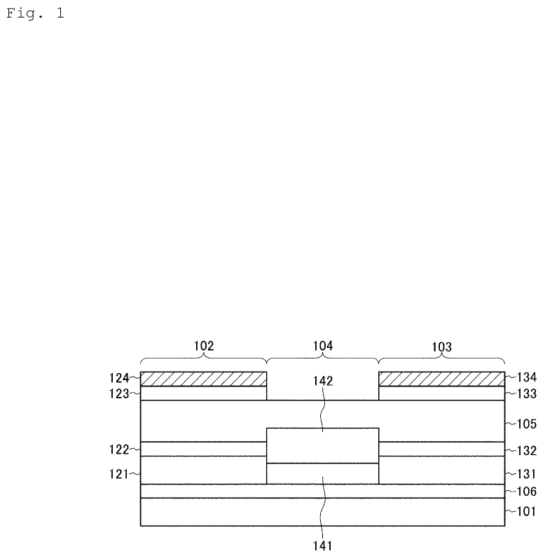

A semiconductor device according to an embodiment of the present invention will be described with reference to FIG. 1. The semiconductor device includes a substrate 101 made of a semi-insulating compound semiconductor, a first optical active element formed on the substrate 101, a second optical active element 103 formed on the substrate 101, and an optical waveguide 104 for optically connecting the first optical active element 102 and the second optical active element 103. The substrate 101 can be made of, for example, InP doped with Fe to have high resistance. The substrate 101 can have a (001) plane of InP as a main surface. FIG. 1 shows a cross-section on a plane parallel to a waveguide direction of light as a carrier wave.

In this example, an etching stop layer 106 formed over the entire region of the substrate 101 is included. The first optical active element 102, the optical waveguide 104, and the second optical active element 103 are formed on the etching stop layer 106. The etching stop layer 106 can be made of, for example, undoped InGaAsP (bandgap wavelength 1.1 μm). The thickness of the etching stop layer 106 can be about 10 nm.

The first optical active element 102 includes a first lower semiconductor layer 121 of a first conductivity type, a first active layer 122 formed on the first lower semiconductor layer 121, and an upper semiconductor layer 105 of a second conductivity type formed on the first active layer 122. In the first optical active element 102, a first contact layer 123 is formed on the upper semiconductor layer 105, and a first p-electrode 124 is formed on the first contact layer 123.

The first lower semiconductor layer 121 can be made of, for example, n-type InP (doping amount: 1E18). The first lower semiconductor layer 121 can have a thickness of about 800 nm. The first active layer 122 can be made of, for example, InGaAsP or InGaAlAs. The first active layer 122 can have a thickness of about 250 nm. The upper semiconductor layer 105 can be made of p-type InP, for example. The first contact layer 123 can be made of, for example, InGaAs into which p-type impurities are introduced at a high concentration. The first optical active element 102 can be, for example, a semiconductor laser.

The second optical active element 103 includes a second lower semiconductor layer 131 of the first conductivity type, a second active layer 132 formed on the second lower semiconductor layer 131, and an upper semiconductor layer 105 formed on the second active layer 132. In the second optical active element 103, a second contact layer 133 is formed on the upper semiconductor layer 105, and a second p-electrode 134 is formed on the second contact layer 133.

The second lower semiconductor layer 131 can be made of, for example, n-type InP. The second active layer 132 can be made of, for example, InGaAsP or InGaAlAs.

Further, the second active layer 132 can have a thickness of about 280 nm. The second contact layer 133 can be made of, for example, InGaAs into which p-type impurities are introduced at a high concentration. The second optical active element 103 can be, for example, an electro-absorption optical modulator (EA modulator).

The first active layer 122 and the second active layer 132 can have a multiple quantum well structure (MQW structure). The first active layer 122 and the second active layer 132 indicate portions including the MQW structure and the upper and lower light confinement layers (SCH), and function as cores of the waveguide structure.

The optical waveguide 104 includes a semi-insulating or undoped third lower semiconductor layer 141, a third active layer 142 formed on the third lower semiconductor layer 141, and an upper semiconductor layer 105 formed on the third active layer 142. The third active layer 142 functions as a core of the optical waveguide 104. In the optical waveguide 104, the third lower semiconductor layer 141 and the upper semiconductor layer 105 function as a clad. The third lower semiconductor layer 141 can be made of i-type InP or high-resistance InP. The third active layer 142 can be made of, for example, InGaAs. The etching stop layer 106, as is well known, is made of a different material from the first lower semiconductor layer 121, the second lower semiconductor layer 131, and the third lower semiconductor layer 141.

The optical waveguide 104 is disposed between the first optical active element 102 and the second optical active element 103 on the substrate 101, functions as an electric separation part between the first optical active element 102 and the second optical active element 103, and optically connects the first optical active element 102 and the second optical active element 103.

In this example, the upper semiconductor layer 105 is formed commonly in the first optical active element 102, the second optical active element 103, and the optical waveguide 104.

Further, the thickness W of the third active layer 142 is equal to or greater than the thickness x of the first active layer 122 and the second active layer 132. A total thickness (W+z) of the third lower semiconductor layer 141 and the third active layer 142 is equal to or greater than a total thickness (x+y) of the first active layer 122 and the first lower semiconductor layer 121, and a total thickness of the second lower semiconductor layer 131 and the second active layer 132. A width (W_{ISO}) of the third active layer 142 in the waveguide direction is equal to or greater than a width (W_{LD}) of the first active layer 122 and the second active layer 132 in the waveguide direction.

In the semiconductor device according to the embodiment, the first optical active element 102 is DC-driven, and the second optical active element 103 can be operated by applying a differential modulation signal between the second lower semiconductor layer 131 and the upper semiconductor layer 105 in the region of the second optical active element 103. A laser beam emitted by driving the first optical active element 102 which is a semiconductor laser is guided through the optical waveguide 104, and modulated in the second optical active element 103 which is a differentially driven EA modulator.

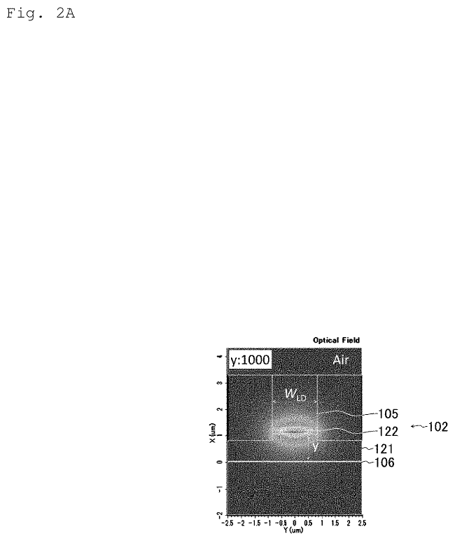

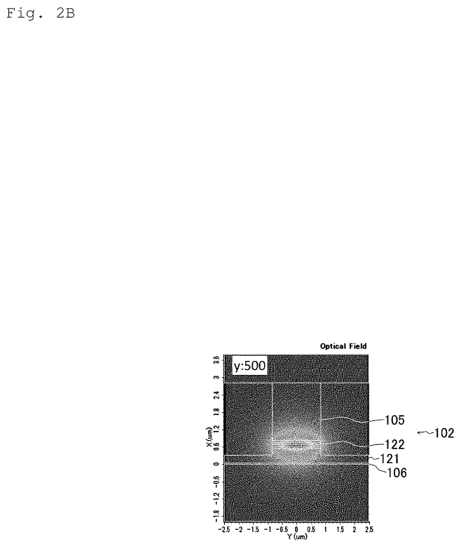

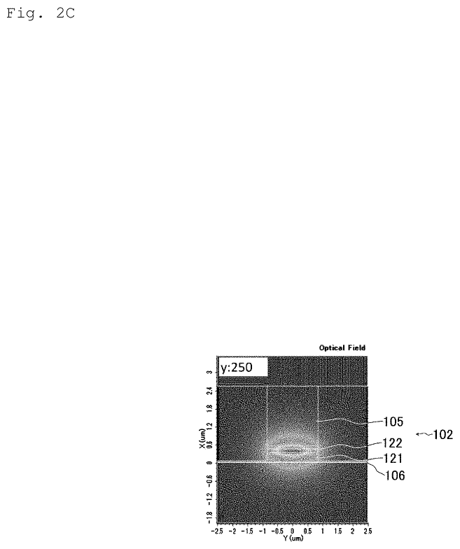

Here, the dimensions mentioned above will be explained in more detail. First, the results obtained by of calculating the electric field strength distribution to estimate the optimal value of the thickness y of the first lower semiconductor layer 121 will be explained with reference to FIGS. 2A, 2B, and 2C. FIGS. 2A, 2B, and 2C show calculation results of the electric field intensity distribution in a cross section perpendicular to the waveguide direction in the first optical active element 102 (second optical active element 103). For this calculation, calculation software “APSS” (version: 2.3 g, manufactured by Apollo Co.) was used.

White lines of FIG. 2A, FIG. 2B, and FIG. 2C indicate an outline of the calculated structure. The distribution indicated by the density in the drawing indicates the distribution of the electric field intensity. A portion of a central part of the first active layer 122 with high concentration has the highest field strength. A portion further away from this and with lower concentration has the weakest field strength.

The waveguide width W_{LD} was, for example, set to 1.7 μm. The structure in which the waveguide portion is buried with InP material was calculated. FIG. 2A is the result calculated for the case where y is 1000. FIG. 2B is the result calculated for the case where y is 500. FIG. 2C is the result calculated for the case where y is 250. The thickness x of the first active layer 122 was set to 300 nm. The compound semiconductor constituting the first active layer 122 was a compound semiconductor having a band gap wavelength of 1.3 μm. The etching stop layer 106 was made of a semiconductor having a bandgap wavelength of 1.1 μm and had a thickness of 30 nm.

When y is 250, the electric field strength distribution oozes into the etching stop layer 106 On the other hand, when y is 1000, the oozing of the electric field intensity distribution to the etching stop layer 106 can be suppressed. Since the etching stop layer 106 is made of a material different from InP constituting the first lower semiconductor layer 121, the second lower semiconductor layer 131, and the third lower semiconductor layer 141, the refractive index becomes higher than that of InP. Therefore, if the value of y is not set to a sufficient value, there is a concern that the electric field intensity distribution of the first optical active element 102 (the second optical active element 103) is optically coupled to the etching stop layer 106, resulting in deterioration of characteristics.

In order to maintain the characteristics of the first optical active element 102 (the second optical active element 103), it is necessary that the electric field intensity distribution suppress the oozing of the electric field intensity distribution into the etching stop layer 106. The amount of oozing to the etching stop layer 106 can be calculated by calculating a light confinement coefficient Γ of the etching stop layer 106. Γ is 0.00023 in the case of y=1000, 0.00089 in the case of y=750, 0.0034 in the case of y=500, and 0.0123 in the case of y=250, respectively. When y=500, Γ is 0.01 or less, and oozing can be sufficiently suppressed.

Next, the third lower semiconductor layer 141 will be described. When the thickness of the first lower semiconductor layer 121 immediately below the first active layer 122 is defined as y, the width of the first active layer 122 in a direction perpendicular to the waveguide direction is defined as A, and the length of the third lower semiconductor layer 141 in the waveguide direction is defined as L, the separation resistance R between the first optical active element 102 and the second optical active element 103 sandwiching the optical waveguide 104 can be expressed as “R=ρ×L/(A×y)” with the resistivity as ρ.

In order to realize the stable operation of the first optical active element 102 and the second optical active element 103, the separation resistance is required to be 10 kΩ or more. For A, 300 μm or more is required for forming the electrodes of the first and second optical active elements 102 and 103. For L, about 250 μm is required to realize the separation between the first contact layer 123 and the second contact layer 133 at the upper part of the upper semiconductor layer 105 of the optical waveguide 104 by, for example, etching process or the like. Although the thinner y can maintain the separation resistance, as described above, it cannot be 500 nm or less because of the oozing of the electric field intensity distribution.

As a result of the calculation, it is necessary for y to be 1000 nm or less to secure a resistance of 10 kΩ as the separation resistance R. In this calculation, the third lower semiconductor layer 141 is made of undoped InP, and an n-polarity impurity of about 1E15 [cm⁻³] is assumed in the first lower semiconductor layer 121 and the second lower semiconductor layer 131. In this case, the resistivity of the third lower semiconductor layer 141 is 1.3 Ωcm.

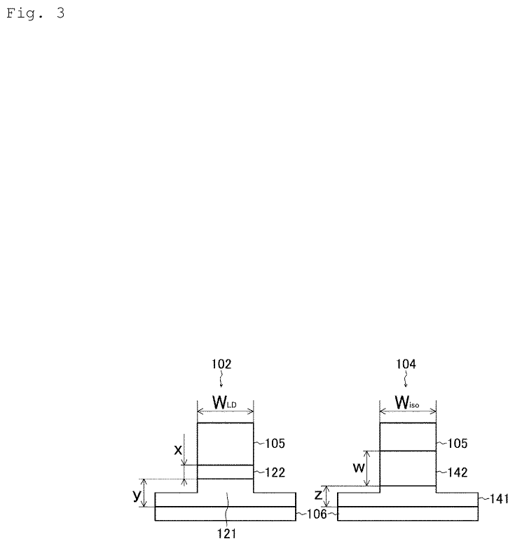

Next, the optical waveguide 104 will be explained. In general, high optical coupling is required between the first optical active element 102 and the optical waveguide 104. The results obtained by performing simulations will be explained regarding this optical coupling. First, the model shown in FIG. 3 we used in the simulation.

In the manufacturing of this semiconductor device, each semiconductor layer constituting the first and second optical active elements 102 and 103 are first subjected to crystal growth, and a part of the semiconductor layer subjected to crystal growth (region to be used as the optical waveguide 104) is removed by etching. Thereafter, the semiconductor layer constituting the optical waveguide 104 is crystal-grown in the removed region. Therefore, w and z of the optical waveguide 104 shown in FIG. 3 vary during manufacturing. Here, for such variations in manufacturing, the relationship between x, y, w, z, W_{LD}, and W_{ISO} having a high tolerance capable of maintaining optical coupling, is shown by calculation.

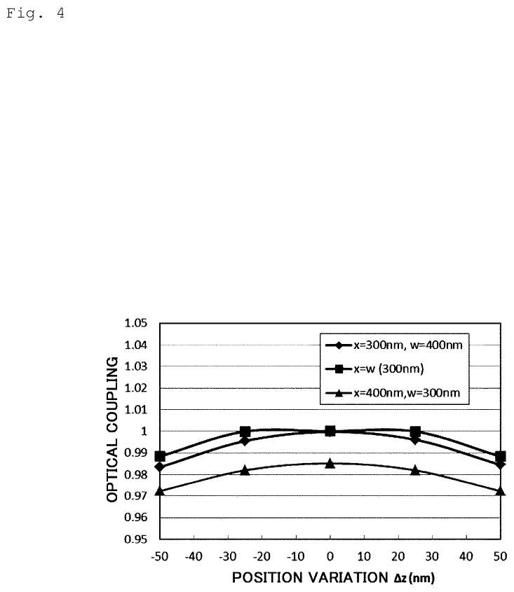

FIG. 4 shows the calculation result of the optical coupling coefficient with respect to the variation Δz of the thickness z of the third lower semiconductor layer 141 of the optical waveguide 104. The calculation was performed as W_{LD}=W_{ISO} (1.7 μm). As shown in FIG. 4, the highest coupling coefficient is shown in the case of x=w. Although it is not easy to form strictly the same thickness in the manufacturing process, it is assumed that x=W is the best, and the state of deterioration of the optical coupling from this condition is examined. A value is set to have tolerance with respect to the variation of the thickness at the time of manufacturing. From FIG. 4, it can be seen that a higher coupling can be maintained when the structure is designed so that w is equal to or thicker than x.

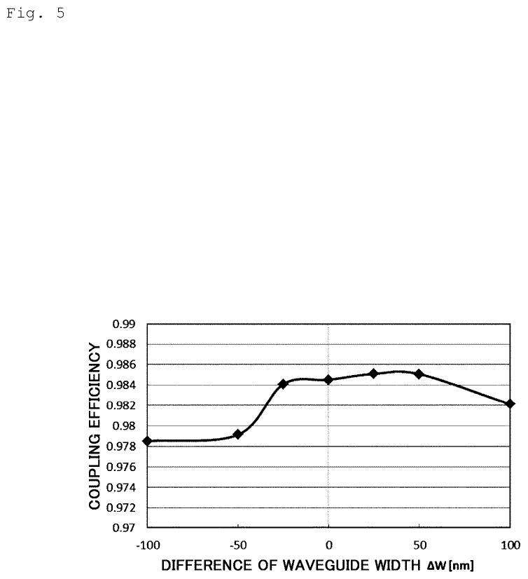

Next, the waveguide width and optical coupling efficiency will be explained. Consider a case where there is a difference of AW between the waveguide width W_{LD} of the first optical active element 102 and the waveguide width W_{ISO} of the optical waveguide 104. FIG. 5 shows a calculation result of the optical coupling efficiency with respect to the difference ΔW of the waveguide width. Calculation in the case where x=300, W=400, Δz=50, W_{LD}=1.7 μm is shown. As shown in FIG. 5, the coupling efficiency becomes higher as the W_{ISO} is slightly wider than the W_{LD}. It can be seen that when the ΔW is about 25 to 50 nm, the coupling efficiency becomes maximum.

When w>x and W_{LD}≤W_{ISO} from the results shown in FIGS. 4 and 5, it is understood that the variation in thickness during manufacturing can be absorbed and high coupling efficiency can be maintained.

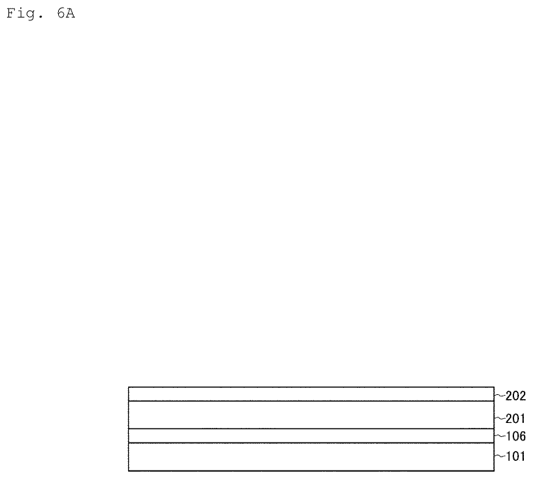

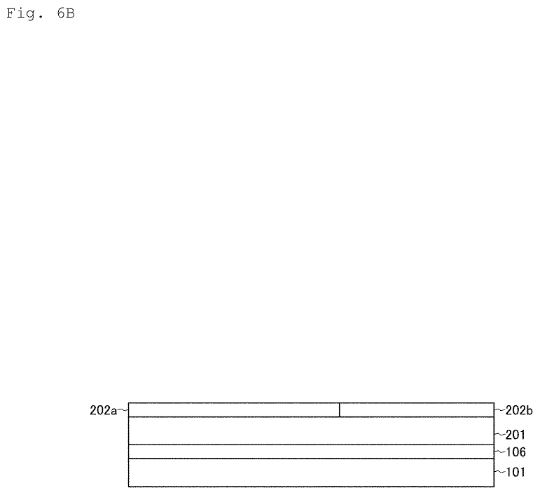

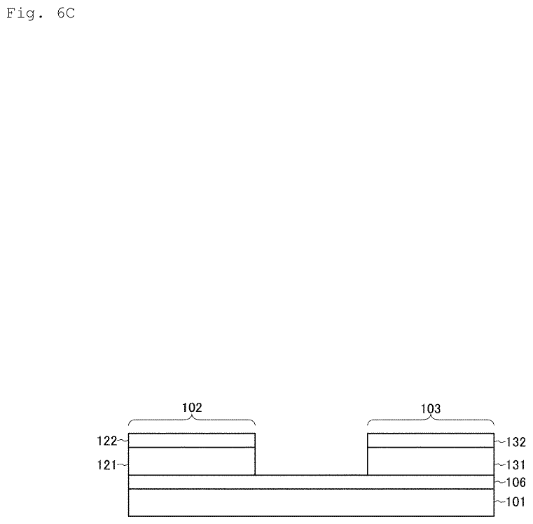

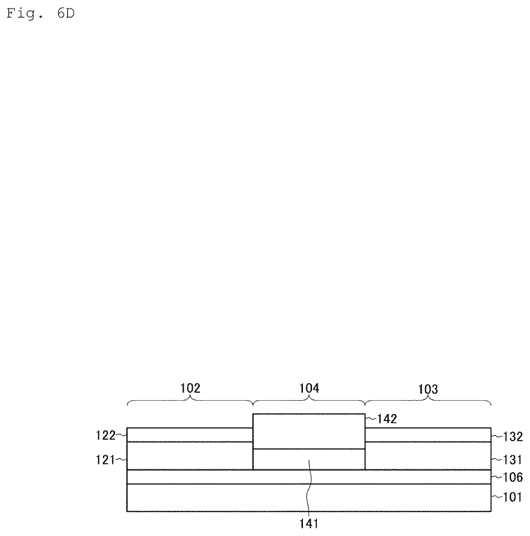

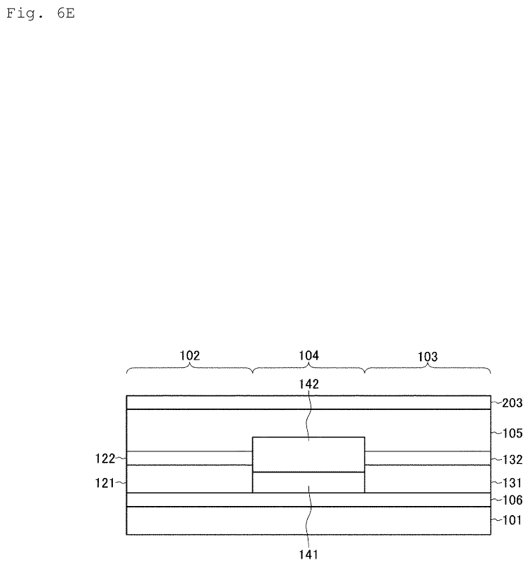

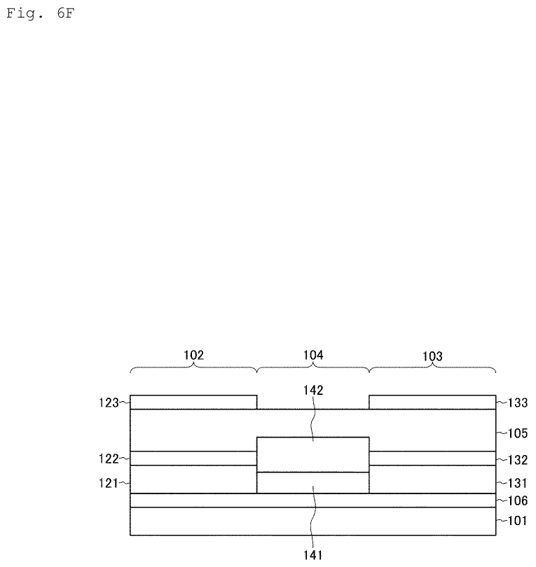

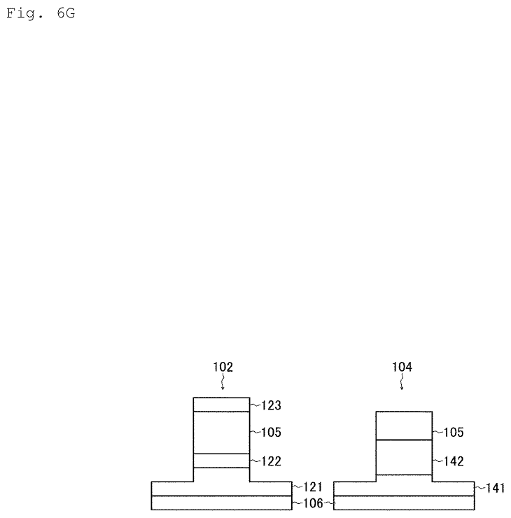

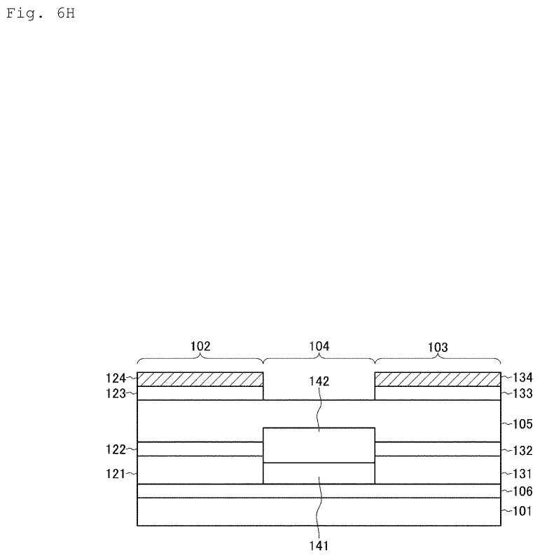

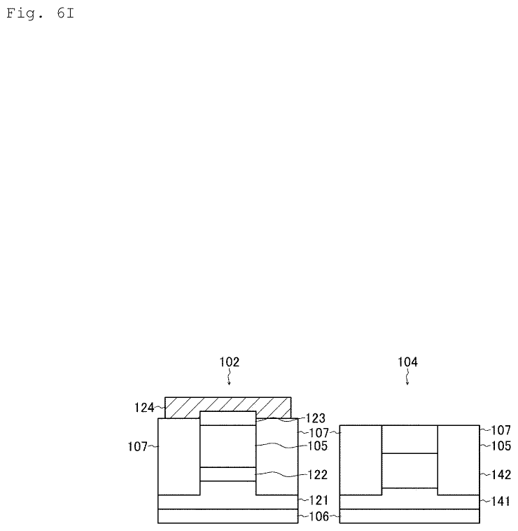

Next, a method for manufacturing a semiconductor device according to an embodiment of the present invention will be described with reference to FIGS. 6A to 6I.

First, as shown in FIG. 6A, the etching stop layer 106 having a thickness of 10 nm is formed on the substrate 101 by crystal growth of undoped InGaAsP. Subsequently, an InP layer 201 with a thickness of 800 nm is formed by crystal growth of n-type InP (doping amount: 1E18). Subsequently, an active layer 202 of InGaAsP having a thickness of 250 nm is formed (crystal growth).

Next, the active layer 202 in the region to be the second optical active element 103 is removed to form the active layer 202a as shown in FIG. 6B, an active layer 202b having a thickness of 280 nm by InGaAsP is formed in a removed place (crystal growth), and the active layer 202a and the active layer 202b are butt-jointed in the waveguide direction (butt-joint process). The active layer 202a and the active layer 202b have a multiple quantum well structure (MQW structure), and have the above-mentioned thickness including upper and lower light confinement layers (SCH) of the MQW structure.

Next, when the predetermined regions of the active layer 202a, the active layer 202b, and the InP layer 201 are removed by etching process using a mask pattern (not shown) formed by a known photolithography technique, as shown in FIG. 6C, a first lower semiconductor layer 121 and a first active layer 122 of the first optical active element 102 are formed, and a second lower semiconductor layer 131 and a second optical active element 103 of the second optical active element 103 are formed. The regions of the first optical active element 102 and the second optical active element 103 serve as the region for forming the optical waveguide 104. The etching process described above can be performed by selective wet etching using the etching stop layer 106.

Next, as shown in FIG. 6D, a third lower semiconductor layer 141 and a third active layer 142 of the optical waveguide 104 are formed by crystal growth. The third lower semiconductor layer 141 can be formed to have a thickness of about 700 nm, and the third active layer 142 can be formed to have a thickness of about 400 nm.

Next, as shown in FIG. 6E, a p-type InP is crystal-grown to a thickness of about 1,500 nm to form the upper semiconductor layer 105, and InGaAs is crystal-grown to a thickness of about 300 nm to form the contact layer 203.

Next, the contact layer 203 in the region of the optical waveguide 104 is removed by etching process using a mask pattern (not shown) formed by a known photolithography technique to form the first contact layer 123 of the first optical active element 102 and the second contact layer 133 of the second optical active element 103, as shown in FIG. 6F. The first contact layer 123 and the second contact layer 133 are formed in a state of being electrically separated from each other in a plane direction parallel to the surface of the upper semiconductor layer 105.

Next, the waveguide of each part is formed by etching process using a mask pattern (not shown) formed by a known photolithography technique as shown in FIG. 6G. The width of the ridge-shaped waveguide structure is set as 1.7 μm in the first optical active element 102 (second optical active element 103), and the width of the ridge-shaped waveguide structure is set as 1.9 μm in the optical waveguide 104. By changing the width of the ridge-shaped waveguide structure portion in the photomask for forming the mask pattern, the aforementioned dimensional change is realized. In this processing, the first lower semiconductor layer 121 (second lower semiconductor layer 131) and the third lower semiconductor layer 141 are left to some extent on both sides of the ridge-shaped waveguide structure.

Next, as shown in FIGS. 6H and 61, InP of a semi-insulating material is subjected to crystal regrowth on the first lower semiconductor layer 121 (second lower semiconductor layer 131) and the third lower semiconductor layer 141 left on both sides of the ridge-shaped waveguide structure, the ridge-shaped waveguide structure is buried with the buried layer 107. Then, a first p-electrode 124 is formed on the first contact layer 123, and a second p-electrode 134 is formed on the second contact layer 133. Although not shown, a first n-electrode electrically connected to the first lower semiconductor layer 121 is formed, and a second n-electrode electrically connected to the second lower semiconductor layer 131 is formed.

In the semiconductor device manufactured by the method described above, the electric resistance between the p-electrode and n-electrode of the first optical active element 102 serving as a laser and the p-electrode and n-electrode of the second optical active element 103 serving as an EA modulator are both 10 kΩ or more. Electric separation between n-electrodes which cannot be realized by a conventional element integrated on the n-substrate can be realized. Further, the optical coupling efficiency of the first optical active element 102 and the optical waveguide 104, which are used as the laser part, can be set to a satisfactory value of about 98% in calculation.

As a result of applying a differential modulation signal to the second optical active element 103 serving as the EA modulator of the manufactured semiconductor device, the stable operation of the first optical active element 102 serving as the laser part, and a clear waveform aperture of the second optical active element 103 were confirmed by reflecting the above-mentioned high electric resistance

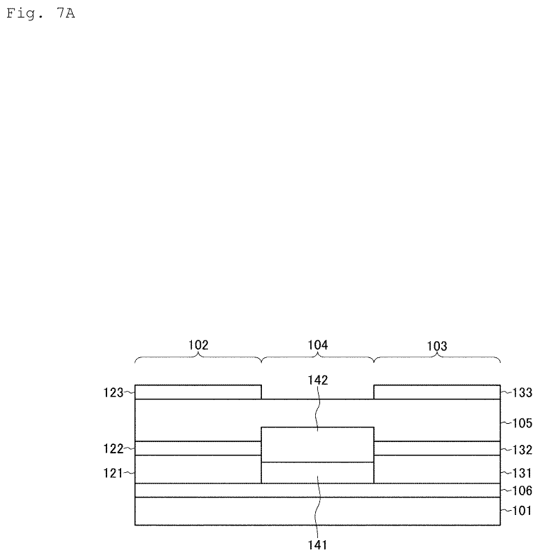

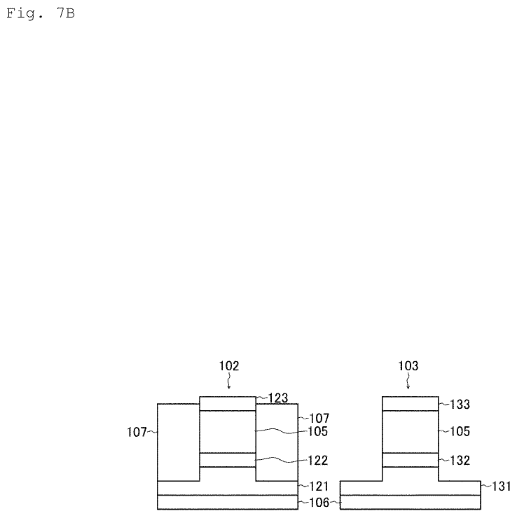

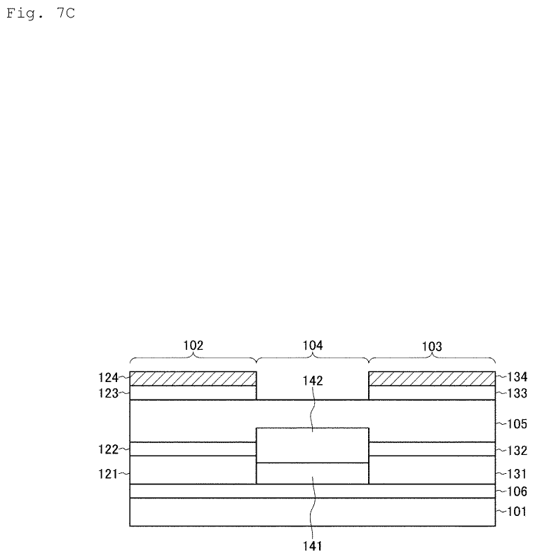

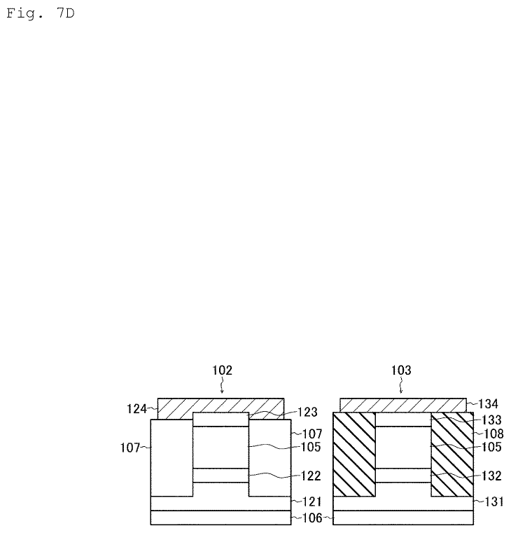

Next, another method for manufacturing a semiconductor device according to an embodiment of the present invention will be described with reference to FIGS. 7A to 7D.

In this manufacturing method, first, in the same way as in the manufacturing method explained above using FIGS. 6A to 6G, each part of the first optical active element 102, the second optical active element 103, and the optical waveguide 104 is formed into a ridge-shaped waveguide structure. Thereafter, as shown in FIGS. 7A and 7B, a buried layer 107 is formed by crystal regrowth of InP of a semi-insulating material, on the first lower semiconductor layer 121 and the third lower semiconductor layer 141 left on both sides of the ridge-shaped waveguide structure in the region (the first optical active element 102 and the optical waveguide 104) other than the second optical active element 103. In this case, in the second optical active element 103, the upper part of the second lower semiconductor layer 131 left on both sides of the ridge-shaped waveguide structure is opened.

Next, as shown in FIGS. 7C and 7D, a buried insulating layer 108 made of a low dielectric constant material is formed, on the second lower semiconductor layer 131 left on both sides of the ridge-shaped waveguide structure in the region of the second optical active element 103. Then, a first p-electrode 124 is formed on the first contact layer 123, and a second p-electrode 134 is formed on the second contact layer 133. Although not shown, a first n-electrode electrically connected to the first lower semiconductor layer 121 is formed, and a second n-electrode electrically connected to the second lower semiconductor layer 131 is formed.

Also in this configuration, both the electric resistances between the p-electrode and the n-electrode of the first optical active element 102 used as a laser and the p-electrode and the n-electrode of the second optical active element 103 used as an EA modulator are set to 10 kΩ or more. Electric separation between n-electrodes which cannot be realized by a conventional element integrated on the n-substrate can be realized. Further, the optical coupling efficiency of the first optical active element 102 and the optical waveguide 104, which are used as the laser part, can be set to a satisfactory value of about 98% in calculation. Further, since the second optical active element 103 serving as the EA modulator is configured to be buried with the buried insulating layer 108 made of a low dielectric constant material, the parasitic capacitance of the element can be reduced as compared with a semiconductor buried structure, and characteristics excellent in high speed performance can be realized.

Also in this configuration, as a result of applying a differential modulation signal to the second optical active element 103 serving as the EA modulator of the fabricated semiconductor device, a stable operation of the first optical active element 102 serving as a laser part and a clear waveform aperture of the second optical active element 103 were confirmed, by reflecting the above-mentioned high electric resistance.

As described above, according to embodiments of the present invention, since the first optical active element and the second optical active element are formed on a substrate made of a semi-insulating compound semiconductor and the optical waveguide functioning as an electric separation part is provided between them, two monolithically integrated optical active elements can be driven in different methods.

Note that it is clear that the present invention is not limited to the embodiments described above and within the technical concept of the present invention and many modifications and combinations can be implemented by those skilled in the art.

### REFERENCE SIGNS LIST

101 Substrate
102 First optical active element
103 Second optical active element
104 Optical waveguide
105 Upper semiconductor layer
106 Etching stop layer
121 First lower semiconductor layer
122 First active layer
123 First contact layer
124 First p-electrode
131 Second lower semiconductor layer
132 Second active layer
133 Second contact layer
134 Second p-electrode
141 Third lower semiconductor layer
142 Third active layer

1-5. (canceled)

6. A semiconductor device comprising:
a substrate made of a semi-insulating compound semiconductor;
a first optical active element on the substrate, the first optical active element including a first lower semiconductor layer of a first conductivity type, a first active layer on the first lower semiconductor layer, and a first upper semiconductor material of a second conductivity type on the first active layer;
a second optical active element on the substrate, the second optical active element including a second lower semiconductor layer of the first conductivity type, a second active layer on the second lower semiconductor layer, and a second upper semiconductor material on the second active layer; and
an optical waveguide on the substrate and disposed between the first optical active element and the second optical active element, the optical waveguide including a semi-insulating or undoped third lower semiconductor layer, a third active layer on the third lower semiconductor layer, and a third upper semiconductor material on the third active layer, wherein the optical waveguide provides an electric separation part between the first optical active element and the second optical active element, and the optical waveguide optically connects the first optical active element and the second optical active element.

7. The semiconductor device according to claim 6, further comprising:
an etching stop layer over an entire region of the substrate,
wherein the first optical active element, the optical waveguide, and the second optical active element are each disposed on the etching stop layer.

8. The semiconductor device according to claim 7, wherein:
the third active layer has a thickness equal to or greater than a thickness of the first active layer; and
a total thickness of the third lower semiconductor layer and the third active layer is equal to or greater than a total thickness of the first lower semiconductor layer and the first active layer.

9. The semiconductor device according to claim 8, wherein:
the thickness of the third active layer is equal to or greater than a thickness of the second active layer; and
the total thickness of the third lower semiconductor layer and the third active layer is equal to or greater than a total thickness of the second lower semiconductor layer and the second active layer.

10. The semiconductor device according to claim 7, wherein:
a width of the third active layer in a waveguide direction is equal to or greater than a width of the first active layer in the waveguide direction.

11. The semiconductor device according to claim 10, wherein:
the width of the third active layer in the waveguide direction is equal to or greater than a width of the second active layer in the waveguide direction.

12. The semiconductor device according to claim 6, wherein
the first optical active element is configured to be DC driven, and
the second optical active element is configured such that a differential modulation signal is applied between the second lower semiconductor layer and the second upper semiconductor material in a region of the second optical active element.

13. The semiconductor device according to claim 6, wherein:
the third active layer has a thickness equal to or greater than a thickness of the first active layer; and
a total thickness of the third lower semiconductor layer and the third active layer is equal to or greater than a total thickness of the first lower semiconductor layer and the first active layer.

14. The semiconductor device according to claim 13, wherein:
the thickness of the third active layer is equal to or greater than a thickness of the second active layer; and
the total thickness of the third lower semiconductor layer and the third active layer is equal to or greater than a total thickness of the second lower semiconductor layer and the second active layer.

15. The semiconductor device according to claim 6, wherein:
a width of the third active layer in a waveguide direction is equal to or greater than a width of the first active layer in the waveguide direction.

16. The semiconductor device according to claim 15, wherein:
the width of the third active layer in the waveguide direction is equal to or greater than a width of the second active layer in the waveguide direction.

17. A semiconductor device comprising:
a substrate made of a semi-insulating compound semiconductor;
a first optical active element on the substrate, the first optical active element including a first lower semiconductor layer, a first active layer on the first lower semiconductor layer, and an upper semiconductor layer on the first active layer, wherein the first lower semiconductor layer and the upper semiconductor layer have opposite conductivity types;
a second optical active element on the substrate, the second optical active element including a second lower semiconductor layer and a second active layer on the second lower semiconductor layer; and
an optical waveguide on the substrate and optically connecting the first optical active element and the second optical active element, the optical waveguide including third lower semiconductor layer and a third active layer on the third lower semiconductor layer, wherein the optical waveguide provides an electric separation part between the first optical active element and the second optical active element.

18. The semiconductor device of claim 17, wherein the third lower semiconductor layer is a semi-insulating or undoped.

19. The semiconductor device according to claim 17, further comprising:
an etching stop layer over an entire region of the substrate,
wherein the first optical active element, the optical waveguide, and the second optical active element are each disposed on the etching stop layer.

20. The semiconductor device according to claim 17, wherein:
the third active layer has a thickness equal to or greater than a thickness of the first active layer a thickness of the second active layer; and
a total thickness of the third lower semiconductor layer and the third active layer is equal to or greater than a total thickness of the first lower semiconductor layer and the first active layer and a total thickness of the second lower semiconductor layer and the second active layer.

21. The semiconductor device according to claim 17, wherein:
a width of the third active layer in a waveguide direction is equal to or greater than a width of the first active layer and a width of the second active layer in the waveguide direction.

22. The semiconductor device according to claim 17, wherein
the first optical active element is configured to be DC driven, and
the second optical active element is configured such that a differential modulation signal is applied between the second lower semiconductor layer and the upper semiconductor layer in a region of the second optical active element.

23. The semiconductor device according to claim 17, wherein the upper semiconductor layer is further disposed on the second active layer and the third active layer.
